(19) United States
(12) Patent Application Publication
(10) Pub. No.: US 2025/0261391 A1
(43) Pub. Date: Aug. 14, 2025

(54) GRAIN GROWTH OF SILICON BY METAL INDUCED CRYSTALLIZATION

(71) Applicant: Applied Materials, Inc., Santa Clara, CA (US)

(72) Inventors: Chang Seok Kang, Santa Clara, CA (US); Hsueh Chung Chen, Cohoes, NY (US); Raghuveer Satya Makala, Campbell, CA (US); Balasubramanian Pranatharthiharan, San Jose, CA (US)

(73) Assignee: Applied Materials, Inc., Santa Clara, CA (US)

(21) Appl. No.: 18/440,209

(22) Filed: Feb. 13, 2024

(51) Int. Cl. H01L 29/66; H01L 21/324; H10B 43/27

(52) U.S. Cl. CPC H10D 30/0413; H01L 21/324; H10B 43/27; H10D 30/025

(57) ABSTRACT

Provided is a method of manufacturing a semiconductor device which improves the grain size of the polysilicon channel and suppresses adverse effects resulting from remaining metal contents. After deposition of the polysilicon channel layer, a capping layer is deposited on the polysilicon channel layer. The capping layer comprises a metal oxide (MOx). The device is then annealed to increase the grain size of the polysilicon channel layer, and then the capping layer is removed.

### TECHNICAL FIELD

Embodiments of the present disclosure pertain to the field of electronic devices and methods and apparatus for manufacturing electronic devices. More particularly, embodiments of the disclosure provide methods for increasing the grain size of the polysilicon channel of 3D NAND devices.

### BACKGROUND

Semiconductor technology has advanced at a rapid pace and device dimensions have shrunk with advancing technology to provide faster processing and storage per unit space. In NAND devices, the string current needs to be high enough to obtain sufficient current to differentiate ON and OFF cells. The string current is dependent on the carrier mobility which is enhanced by enlarging the grain size of the silicon channel.

As the number of memory stacks increases, the cell current of a string cell decreases. One of the causes of small string current is the smaller electron mobility of the polysilicon channel. Mobility of electrons in the silicon channel is highly dependent on the grain size of polysilicon channel. The larger the grain size, the higher the mobility of the electron. Metal induced crystallization (MIC) has been used to increase the grain size polysilicon, but the results have been residual metal content in the polysilicon channel, leading to an increase in leakage current at the off state of the cell transistor.

Accordingly, there is a need in the art for 3D NAND devices and methods of manufacture of said devices having polysilicon channels with increased grain sizes.

### SUMMARY

One or more embodiments of the disclosure are directed to semiconductor devices. In one or more embodiments, the method comprises: depositing a silicon layer on a substrate, the silicon layer having a grain size less than 0.1 μm; depositing a capping layer on the silicon layer, the capping layer comprising a metal oxide; and annealing the substrate at a temperature in a range of from 300° C. to 1100° C. to increase the grain size of the silicon layer.

Additional embodiments of the disclosure are directed to methods of forming aa semiconductor memory device. In one or more embodiments, the method comprises: depositing cell dielectric layers in a plurality of memory holes extending through a memory stack, the memory stack comprising a plurality of alternating layers of a first layer and a second layer on a substrate; depositing a silicon layer on the cell dielectric layer, the silicon layer having a grain size less than 0.1 μm; depositing a capping layer on the silicon layer, the capping layer comprising a first aluminum oxide layer having a composition of Al₂O_{(3+δ)}, wherein 0<δ≤3, and a second aluminum oxide layer having a composition of Al₂O_{(3+δ)}, wherein δ≥0; and annealing the substrate at a temperature in a range of from 300° C. to 1100° C. to increase the grain size of the silicon layer.

### BRIEF DESCRIPTION OF THE DRAWING

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only typical embodiments of this disclosure and are therefore not to be considered limiting of its scope, for the disclosure may admit to other equally effective embodiments. The embodiments as described herein are illustrated by way of example and not limitation in the figures of the accompanying drawings in which like references indicate similar elements.

FIG. 1 depicts a flow process diagram of a method of forming a memory device according to one or more embodiments described herein;

FIGS. 2A-2D illustrate cross-sectional views of a substrate according to one or more embodiments;

FIGS. 3A-3T illustrate cross-sectional views of a memory device being processed according to one or more embodiments; and

FIG. 4 illustrates a cluster tool according to one or more embodiments.

### DETAILED DESCRIPTION

Before describing several exemplary embodiments of the disclosure, it is to be understood that the disclosure is not limited to the details of construction or process steps set forth in the following description. The disclosure is capable of other embodiments and of being practiced or being carried out in various ways.

As used in this specification and the appended claims, the terms “precursor”, “reactant”, “reactive gas” and the like are used interchangeably to refer to any gaseous species that can react with the substrate surface.

In the following description, numerous specific details, such as specific materials, chemistries, dimensions of the elements, etc. are set forth in order to provide thorough understanding of one or more of the embodiments of the present disclosure. It will be apparent, however, to one of ordinary skill in the art that the one or more embodiments of the present disclosure may be practiced without these specific details. In other instances, semiconductor fabrication processes, techniques, materials, equipment, etc., have not been described in great detail to avoid unnecessarily obscuring of this description. Those of ordinary skill in the art, with the included description, will be able to implement appropriate functionality without undue experimentation.

While certain exemplary embodiments of the disclosure are described and shown in the accompanying drawings, it is to be understood that such embodiments are merely illustrative and not restrictive of the current disclosure, and that this disclosure is not restricted to the specific constructions and arrangements shown and described because modifications may occur to those ordinarily skilled in the art.

Embodiments of the disclosure provide methods for enlarging the grain size of silicon channels to improve the channel mobility and the string current for 3D NAND arrays. One or more embodiments provide a fabrication method which improves the grain size of polysilicon and suppresses adverse effects resulting from remaining metal contents. In one or more embodiments, after deposition of the polysilicon layer, a capping layer is deposited on the polysilicon layer. In one or more embodiments, the capping layer is a bilayer, with a first aluminum oxide (AlO) layer that has a thickness in a range of from 1 nm to 10 nm and is aluminum rich, having a composition of Al₂O_{(3-δ)}, wherein 0<δ≤3. The capping layer includes a second aluminum oxide layer formed on the first aluminum oxide layer. The second aluminum oxide layer has a thickness in a range of from 5 nm to 5 nm and has a composition of Al₂O₃. Without intending to be bound by theory, it is thought that the aluminum of the capping layer serves as the metal for the subsequent metal induced crystallization. In one or more embodiments, during anneal, the out-diffusion of aluminum is prevented or minimized by the second aluminum oxide layer. The amount of aluminum is controlled by how metal (aluminum) rich and how thick the first aluminum oxide layer is. In one or more embodiments, the presence of the capping layer advantageously increases the grain size of the polysilicon channel layer during annealing.

Some embodiments of the disclosure advantageously provide 3D NAND devices that have increased carrier mobility for highly stacked three-dimensional memory devices. Some embodiments advantageously provide NAND structures which incorporate MIC processing to current 3D NAND devices. Some embodiments advantageously eliminate or minimize metal contamination of the polysilicon channel layer.

One or more embodiments of the disclosure are described with reference to the Figures. In the method of one or more embodiments, logic or memory devices are fabricated. In specific embodiments, 3-D NAND cell structures are fabricated. In some embodiments, the processing method is performed in a processing tool without breaking vacuum.

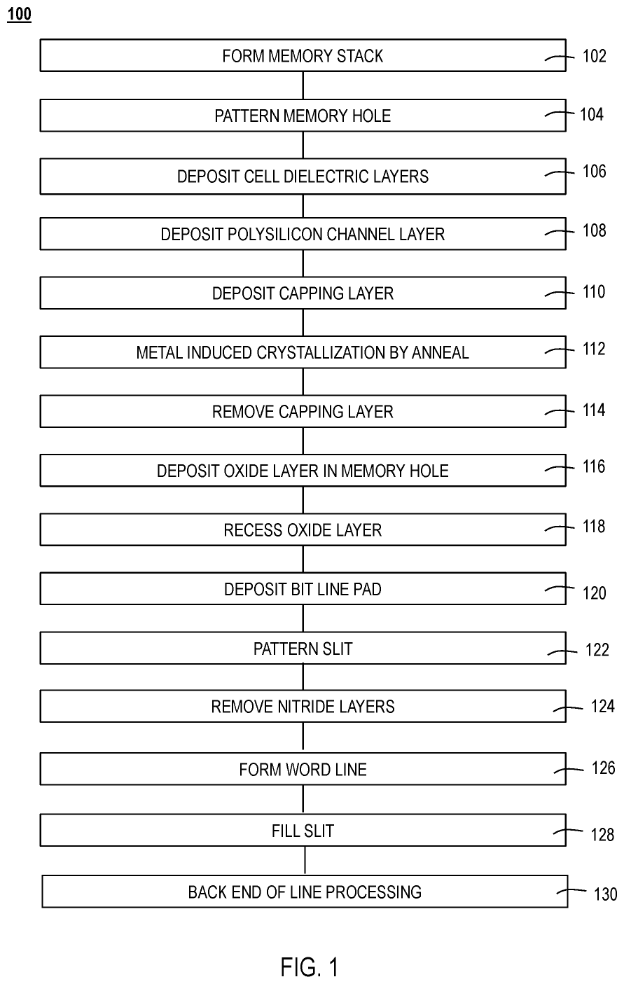

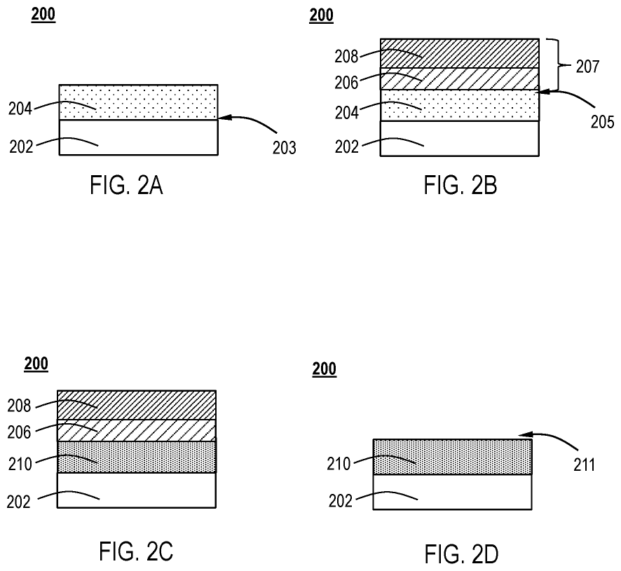

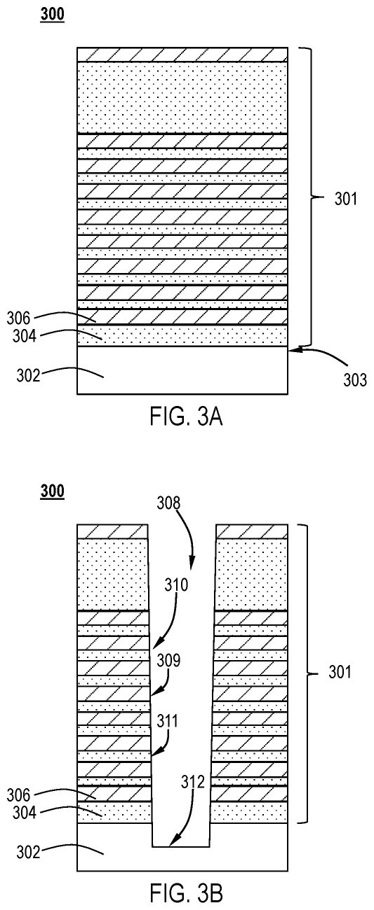

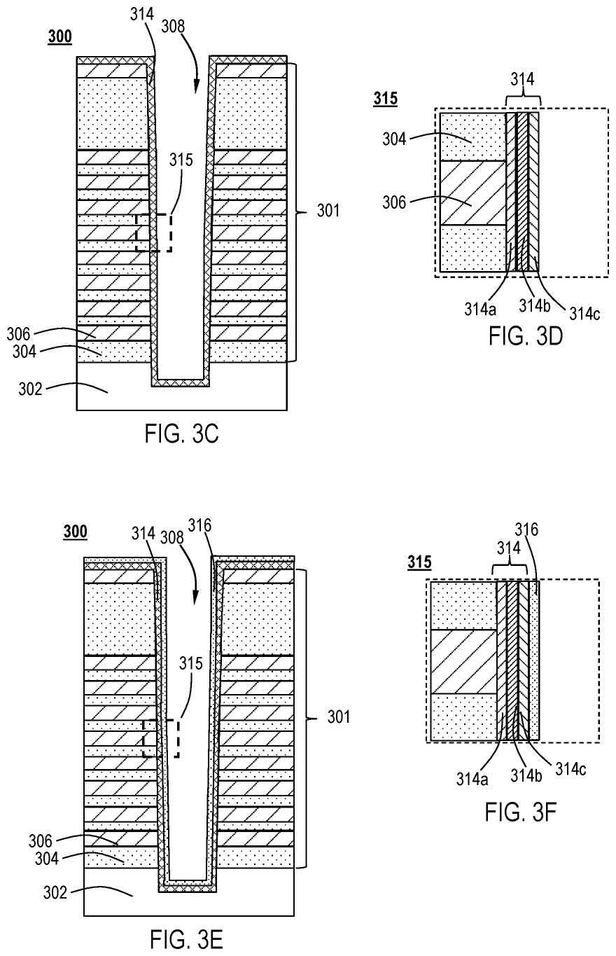

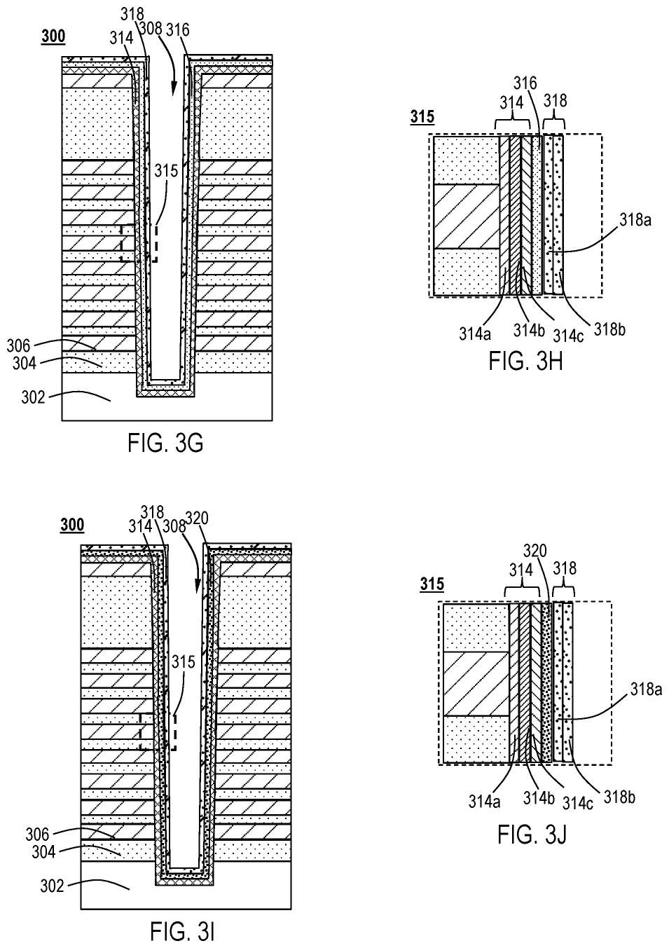

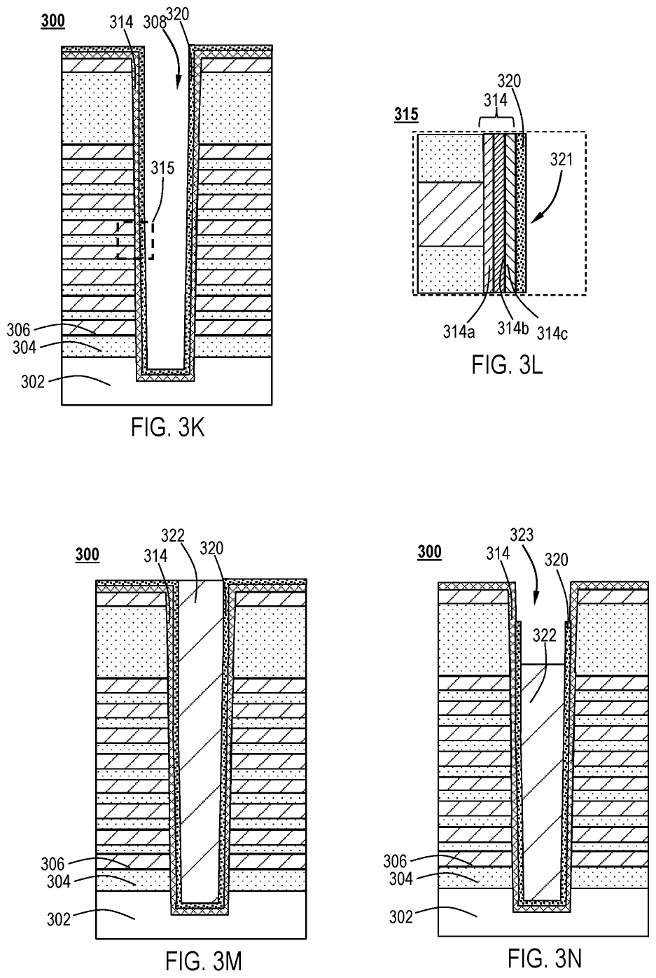

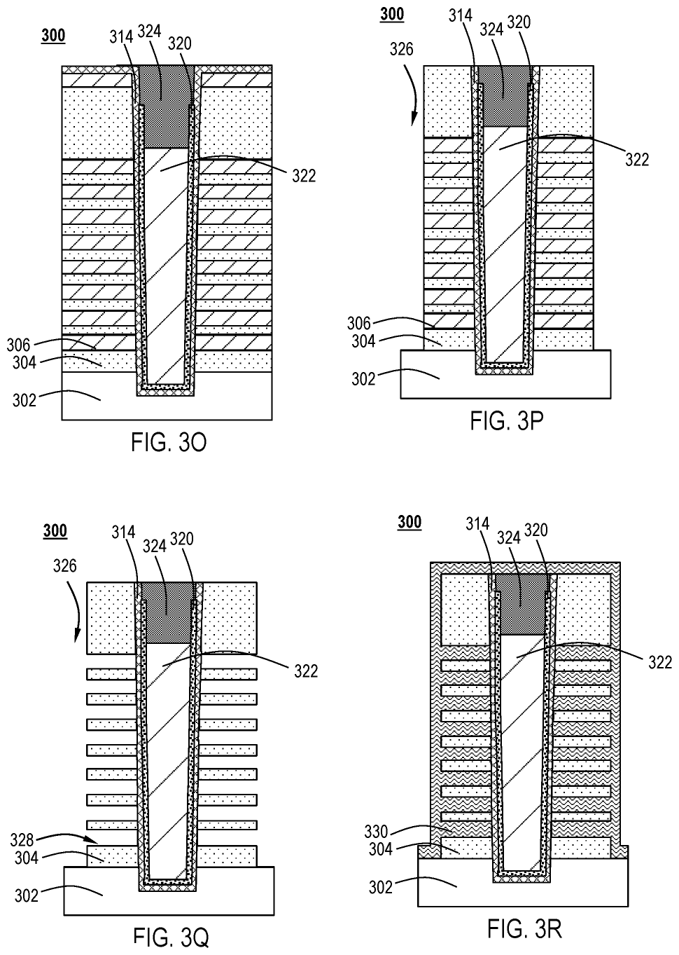

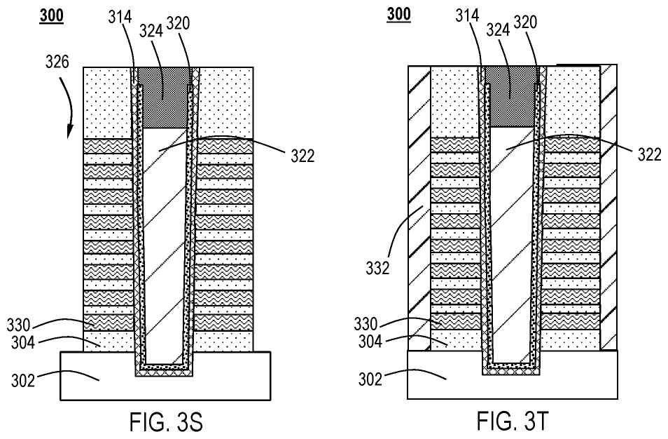

FIG. 1 illustrates a process flow diagram for an exemplary method 100 for forming a memory device. The skilled artisan will recognize that the method 100 can include any or all of the processes illustrated. Additionally, the order of the individual processes can be varied for some portions. The method 100 can start at any of the enumerated processes without deviating from the disclosure. FIGS. 2A-2D illustrate cross-sectional views of a substrate being processed according to one or more embodiments. FIGS. 3A-3R illustrate cross-sectional views of a portion of a memory device 300 following the process flow illustrated for the method 100 in FIG. 1.

Referring to FIGS. 2A to 2D, one or more embodiments provide methods for enlarging the grain size of silicon channels to improve the channel mobility and the string current for 3D NAND arrays. In one or more embodiments, a substrate 202 is provided. As used herein, the term “provided” means that the substrate is made available for processing (e.g., positioned in a processing chamber). In one or more embodiments, a silicon layer 204 is formed on a top surface 203 of the substrate 202.

The substrate 202 can be any suitable material known to the skilled artisan. As used in this specification and the appended claims, the term “substrate” refers to a surface, or portion of a surface, upon which a process acts. It will also be understood by those skilled in the art that reference to a substrate can refer to only a portion of the substrate unless the context clearly indicates otherwise. Additionally, reference to depositing on a substrate can mean both a bare substrate and a substrate with one or more films or features deposited or formed thereon.

In one or more embodiments, the silicon layer 204 is formed on the top surface 203 of the substrate 202. According to one or more embodiments, the term “on”, with respect to a film or a layer of a film, includes the film or layer being directly on a surface, for example, a substrate surface, as well as there being one or more underlayers between the film or layer and the surface, for example the substrate surface. Thus, in one or more embodiments, the phrase “on the substrate surface” is intended to include one or more underlayers. In other embodiments, the phrase “directly on” refers to a layer or a film that is in contact with a surface, for example, a substrate surface, with no intervening layers. Thus, the phrase “a layer directly on the substrate surface” refers to a layer in direct contact with the substrate surface with no layers in between. In one or more embodiments, the silicon layer 204 comprises amorphous silicon (Si). The silicon layer 204 may have any suitable thickness. In one or more embodiments, the silicon layer has a thickness in a range of from 5 nm to 100 nm. In one or more embodiments, the silicon layer 204 has a low grain size when deposited on the substrate 202. As used herein, “low grain size” refers to a silicon layer having a grain size less than 0.1 μm.

Referring to FIG. 2B, in one or more embodiments a capping layer 207 is formed on a top surface 205 of silicon layer 204. In one or more embodiments, the capping 207 comprises metal oxide layer. The metal of the capping layer can comprise any suitable metal known to the skilled artisan. In one or more embodiments, the metal comprises one or more of aluminum (Al), nickel (Ni), cobalt (Co), zirconium (Zr), palladium (Pd), and the like.

In one or more embodiments, the capping layer 207 may have any suitable thickness. In some embodiments, the capping layer 207 has a thickness in a range of from 1 nm to 50 nm.

In some embodiments, the capping layer 207 is a bilayer of a metal rich oxide material and a metal oxide. Thus, in one or more embodiments, the capping layer 207 may comprise a first metal oxide layer and a second metal oxide layer on the first metal oxide layer. In one or more embodiments, the thickness of the capping layer 207 1% to 10% first metal oxide layer and 9% to 90% second metal oxide layer. In one or more embodiments, the first metal oxide layer has a thickness in a range of from 0.5 nm to 5 nm, and the second metal oxide layer has a thickness in a range of from 1 nm to 50 nm. In one or more embodiments, the composition of the first metal oxide layer is different from the composition of the second metal oxide layer. In some embodiments, the first metal oxide layer has a composition of MOₓ, wherein 0≤x≤1. In one or more embodiments, the second metal oxide layer has a composition of MO_{y}, wherein y≥1. In one or more embodiments, the metal of the first metal oxide layer and the metal of the second metal oxide layer may be the same or may be different. In one or more embodiments, the metal of the first metal oxide layer is a metal selected from one or more of aluminum (Al), nickel (Ni), cobalt (Co), zirconium (Zr), and palladium (Pd). In one or more embodiments, the metal of the second metal oxide layer is a metal selected from one or more of aluminum (Al), nickel (Ni), cobalt (Co), zirconium (Zr), and palladium (Pd).

In one or more specific embodiments, the capping layer 207 is a bilayer, with a first aluminum oxide (AlO) layer 206 that has a thickness in a range of from 1 nm to 10 nm and is aluminum rich, having a composition of Al₂O_{(3-δ)}, wherein 0<δ≤3 that is formed on the top surface 205 of the silicon layer 204. In one or more embodiments, the capping layer 207 includes a second aluminum oxide layer 208 formed on the first aluminum oxide layer 206. In one or more embodiments, the second aluminum oxide layer 208 has a thickness in a range of from 5 nm to 5 nm and has a composition of Al₂O₃. Without intending to be bound by theory, it is thought that the aluminum of the capping layer 207 serves as the metal for the subsequent metal-induced crystallization (MIC).

With reference to FIG. 2C, in one or more embodiments, the device 200 is annealed in a furnace with a rapid thermal anneal (RTA) at a temperature in a range of from 300° C. to 1100° C. for a time period in a range of from 1 min to 24 hours in an ambient atmosphere of an inert gas, e.g., nitrogen (N₂), argon (Ar), or a mixture of nitrogen and argon (N₂/Ar).

In one or more embodiments, annealing the device serves as a mechanism of metal-induced crystallization (MIC). As used herein, the term “metal-induced crystallization (MIC)” refers to a method by which amorphous carbon (a-C), amorphous silicon (a-Si), amorphous oxides, and amorphous germanium (Ge) can be turned into their polycrystalline phases. Annealing the memory device drives the metal through the polysilicon layer to crystallize the polysilicon to form a single crystalline-like silicon layer. The amount of metal remaining at the single crystalline silicon is negligible, and the metal remains at the area far from memory cells. Thus, in one or more embodiments, the annealing of the device results in the metal-induced crystallization of the silicon layer 204, converting the silicon layer 204 to a polysilicon layer 210.

In one or more embodiments, during anneal, the out-diffusion of aluminum (AI) from the capping layer 207 is prevented or minimized by the second aluminum oxide layer 208. The amount of aluminum (Al) is controlled by how metal (aluminum) rich and how thick the first aluminum oxide layer 206 is. In one or more embodiments, the presence of the capping layer 207 advantageously increases the grain size of the silicon layer 204 to form the polysilicon layer 210 during annealing.

With reference to FIG. 2D, in one or more embodiments, the capping layer 207 is then removed to expose the top 211 surface of polysilicon layer 210 for further processing.

With reference to FIG. 1, at operation 102, a memory stack is formed. At operation 104, a memory hole is patterned through the memory stack. At operation 106, cell dielectric layers, e.g., transistor layers are deposited in the memory hole. At operation 108, a polysilicon channel layer is formed on the cell dielectric layers. At operation 110, a capping layer is formed on the polysilicon channel layer. At operation 112, the metal-induced crystallization of the polysilicon channel layer occurs by annealing the device with the capping layer thereon. At operation 114, the capping layer is removed. At operation 116, an oxide layer is deposited in the memory hole on the crystallized polysilicon layer. At operation 118, the oxide layer is recessed to form a recess. At operation 120, the bit line pad is formed. At operation 122, the device is slit patterned. At operation 124, the sacrificial layers of the memory stack are removed. At operation 126, the word line is formed. At operation 128, the slit is filled with a dielectric material. At operation, 130 the device is then subjected to back end of the line processing.

FIGS. 3A to 3S illustrate a portion of a memory device 300 following the process flow illustrated for the method 100 in FIG. 1.

FIG. 3A illustrates an initial or starting memory stack 301 of an electronic device 300 in accordance with one or more embodiments of the disclosure. In some embodiments, the electronic device 300 shown in FIG. 3A is formed on the bare substrate 302 in layers, as illustrated. The electronic device of FIG. 3A is made up of a substrate 302 and a memory stack 301.

In some unillustrated embodiments, a common source line may be formed on the substrate 302 before the memory stack 301 is deposited. The common source line may also be referred to as the semiconductor layers. The common source line can be formed by any suitable technique known to the skilled artisan and can be made from any suitable material including, but not limited to, polysilicon (poly-Si). In some embodiments, the common source line comprises several different conductive or semiconductor materials. For example, in one or more embodiments, the common source line may comprise a polysilicon layer on the substrate 102, a sacrificial layer on the polysilicon layer, and a second polysilicon layer on the sacrificial layer.

The substrate 302 can be any suitable material known to the skilled artisan. As used in this specification and the appended claims, the term “substrate” refers to a surface, or portion of a surface, upon which a process acts. It will also be understood by those skilled in the art that reference to a substrate can refer to only a portion of the substrate unless the context clearly indicates otherwise. Additionally, reference to depositing on a substrate can mean both a bare substrate and a substrate with one or more films or features deposited or formed thereon.

A “substrate” as used herein, refers to any substrate or material surface formed on a substrate upon which film processing is performed during a fabrication process. For example, a substrate surface on which processing can be performed include materials such as silicon, silicon oxide, strained silicon, silicon on insulator (SOI), carbon doped silicon oxides, amorphous silicon, doped silicon, germanium, gallium arsenide, glass, sapphire, and any other materials such as metals, metal nitrides, metal alloys, and other conductive materials, depending on the application. Substrates include, without limitation, semiconductor wafers. Substrates may be exposed to a pretreatment process to polish, etch, reduce, oxidize, hydroxylate, anneal and/or bake the substrate surface. In addition to film processing directly on the surface of the substrate itself, in the present disclosure, any of the film processing steps disclosed may also be performed on an under-layer formed on the substrate as disclosed in more detail below, and the term “substrate surface” is intended to include such under-layer as the context indicates. Thus, for example, where a film/layer or partial film/layer has been deposited onto a substrate surface, the exposed surface of the newly deposited film/layer becomes the substrate surface.

In one or more embodiments, the memory stack 301 in the illustrated embodiment comprises a plurality of alternating first layers 304 and second layers 306 formed on a top surface 303 of the substrate 302. While the memory stack 301, illustrated in FIG. 3A, has eight pairs of alternating first layers 304 and second layers 306, one of skill in the art recognizes that this is merely for illustrative purposes only. The memory stack 301 may have any number of alternating first layers 304 and second layers 306. For example, in some embodiments, the memory stack 301 comprises 192 pairs of alternating first layers 304 and second layers 306. In other embodiments, the memory stack 301 comprises greater than 50 pairs of alternating first layers 304 and second layers 306, or greater than 100 pairs of alternating first layers 304 and second layers 306, or greater than 300 pairs of alternating first layers 304 and second layers 306.

In one or more embodiments, the second layers 306 are replacement layers or sacrificial layers. In one or more embodiments, the first layers 304 and the second layers 306 independently comprise a dielectric material. In one or more embodiments, the dielectric material may comprise any suitable dielectric material known to the skilled artisan. As used herein, the term “dielectric material” refers to an electrical insulator that can be polarized in an electric field. In some embodiments, the dielectric material comprises one or more of oxides, carbon doped oxides, porous silicon dioxide (SiO₂), silicon dioxide (SiO), silicon nitride (SiN), silicon dioxide/silicon nitride, carbides, oxycarbides, nitrides, oxynitrides, oxycarbonitrides, polymers, phosphosilicate glass, fluorosilicate (SiOF) glass, or organosilicate glass (SiOCH).

In one or more embodiments, the second layers 306 comprise a material that is etch selective relative to the first layers 304 so that the second layers 306 can be removed without substantially affecting the first layers 304. In one or more embodiments, the first layers 304 comprise an oxide layer. In one or more specific embodiments, the first layers 304 comprise silicon oxide (SiOₓ) layers. In one or more embodiments, the second layers 306 comprise a nitride layer. In one or more embodiments, the second layers 306 comprise silicon nitride (SiN) layers. Accordingly, in one or more embodiments, the memory stack 301 is an oxide/nitride memory stack.

The individual alternating layers may be formed to any suitable thickness. In some embodiments, the thickness of each second layer 306 is approximately equal. In one or more embodiments, each second layer 306 has a second layer thickness. In some embodiments, the thickness of each first layer 304 is approximately equal. As used in this regard, thicknesses which are approximately equal are within +/−5% of each other. In one or more embodiments, the first layers 304 have a thickness in a range of from about 0.5 nm to about 30 nm, including about 1 nm, about 3 nm, about 5 nm, about 7 nm, about 10 nm, about 12 nm, about 15 nm, about 17 nm, about 20 nm, about 22 nm, about 25 nm, about 27 nm, and about 30 nm. In one or more embodiments the first layer 304 has a thickness in the range of from about 0.5 to about 40 nm.

In one or more embodiments, the second layers 306 have a thickness in a range of from about 0.5 nm to about 30 nm, including about 1 nm, about 3 nm, about 5 nm, about 7 nm, about 10 nm, about 12 nm, about 15 nm, about 17 nm, about 20 nm, about 22 nm, about 25 nm, about 27 nm, and about 30 nm. In one or more embodiments, the second layer 112 has a thickness in the range of from about 0.5 to about 40 nm.

In one or more embodiments, the first layers 304 and second layers 306 are deposited by chemical vapor deposition (CVD) or physical vapor deposition (PVD). In some embodiments, the first layers 304 and the second layers 306 are deposited by plasma enhanced chemical vapor deposition (PE-CVD).

With reference to FIG. 1. And FIG. 3B, at operation 104 a memory hole 308 is opened/patterned through the memory stack 301. While only one memory hole 308 is shown in the illustrated embodiments, one of skill in the art recognizes that there may be a plurality of memory holes formed through the memory stack 301. In some embodiments, opening the memory hole 308 comprises etching through the memory stack 301 and into substrate 302. The memory hole 308 has sidewalls 310 that extend through the memory stack 308 exposing surfaces 309 of the second layers 306 and surfaces 311 of the first layers 304.

The memory hole 308 extends a distance into the substrate 302 so that sidewall surfaces 310, and bottom 312 of the memory hole 308 are formed within the substrate 302. The bottom 312 of the memory hole 308 can be formed at any point within the thickness of the substrate 302. In some embodiments, the memory hole 308 extends a thickness into the substrate 302 in the range of from about 10% to about 90%, or in the range of from about 20% to about 80%, or in the range of from about 30% to about 70%, or in the range of from about 40% to about 60% of the thickness of the substrate 302. In some embodiments, the memory hole 308 extends a distance into the substrate 302 by greater than or equal to 10 nm. In some embodiments, the memory hole 308 extends from a top surface of the memory stack 301 through the memory stack 301 to a bottom surface of the substrate 302.

In one or more embodiments, the memory hole 308 may have any suitable critical dimension. In some embodiments, the critical dimension of the memory hole 308 is in a range of from 80 nm to 120 nm.

With reference to FIG. 1 and FIGS. 3C and 3D, at operation 106, cell dielectric layers, e.g., transistor layers, 314 are formed in the memory hole 308. The cell dielectric layers 314 can be formed by any suitable technique known to the skilled artisan. In some embodiments, the cell dielectric layers 314 are formed by a conformal deposition process. In some embodiments, the cell dielectric layers 314 are formed by one or more of atomic layer deposition or chemical vapor deposition.

In one or more embodiments, the deposition of the cell dielectric layers 314 is substantially conformal. As used herein, a layer which is “substantially conformal” refers to a layer where the thickness is about the same throughout (e.g., on the top, middle and bottom of sidewalls and on the bottom of the memory hole 308). A layer which is substantially conformal varies in thickness by less than or equal to about 5%, 2%, 1% or 0.5%. FIG. 3D is an enlarged view 315 of a portion of the device illustrated in FIG. 3C. With reference to FIG. 3D, the cell dielectric layers 314 in the memory hole 308 may comprise one or more of a blocking oxide layer 314a, a trap layer 314b, and a tunnel oxide layer 314c.

The cell dielectric layers 314 can have any suitable thickness depending on, for example, the dimensions of the memory hole 308. In some embodiments, the cell dielectric layers 314 have a thickness in the range of from about 0.5 nm to about 50 nm, or in the range of from about 0.75 nm to about 35 nm, or in the range of from about 1 nm to about 20 nm.

Referring to FIG. 1 and FIGS. 3E and 3F, at operation 108, a channel layer 316 is deposited on the cell dielectric layers 314. FIG. 3F is an enlarged view 315 of a portion of the device illustrated in FIG. 3E. In one or more embodiments, the channel layer 316 comprises amorphous silicon (a-Si) or polysilicon. The channel layer 316 can be formed by any suitable technique known to the skilled artisan. In some embodiments, the channel layer 316 is formed by a conformal deposition process. In some embodiments, the channel layer 316 is formed by one or more of atomic layer deposition or chemical vapor deposition. In one or more embodiments, the channel layer 316 is grown using a precursor, e.g., dichlorosilane (DCS), silane, or trichlorosilane (TCS), in an ambient of hydrogen (H₂), at the temperature ranging from 400° C. to 1100° C. In one or more embodiments, the deposition of the channel layer 316 is substantially conformal.

With reference to FIG. 1 and FIGS. 3G and 3H, at operation 110, in one or more embodiments a capping layer 318 is formed on the channel layer 316. In one or more embodiments, as illustrated in FIG. 3H, which is an enlarged view 315 of a portion of the device illustrated in FIG. 3G, the capping layer 318 comprises a bilayer of a metal rich material 318a and a metal oxide 318b. The metal of the capping layer 318 may comprise any suitable metal known to the skilled artisan. In one or more embodiments, the metal of the capping layer 318 comprises one or more of aluminum (Al), nickel (Ni), cobalt (Co), palladium (Pd), and the like.

In one or more embodiments, the capping layer 318 is a bilayer, with a first aluminum oxide (AIO) layer 318a that has a thickness in a range of from 1 nm to 10 nm and is aluminum rich, having a composition of Al₂O_{(3-δ)}, wherein 0<δ≤3 formed on the channel layer 316. In one or more embodiments, the capping layer 318 includes a second aluminum oxide layer 318b formed on the first aluminum oxide layer 318a. In one or more embodiments, the second aluminum oxide layer 318b has a thickness in a range of from 5 nm to 5 nm and has a composition of Al₂O₃. Without intending to be bound by theory, it is thought that the aluminum of the capping layer 318 serves as the metal for the subsequent metal-induced crystallization (MIC).

The capping layer 318 can be formed by any suitable technique known to the skilled artisan. In some embodiments, the capping layer 218 is formed by a conformal deposition process. In some embodiments, the capping layer 318 is formed by one or more of atomic layer deposition or chemical vapor deposition. In one or more embodiments, the deposition of the capping layer 318 is substantially conformal.

In one or more embodiments, to ensure bigger grain size in the subsequent MIC process, a seed layer may be formed so that lower nuclei density can be obtained using a deposition and etch process in ambient.

With reference to FIG. 1 and FIGS. 31 and 3J, at operation 112, in one or more embodiments, the device 300 is annealed in a furnace with a rapid thermal anneal (RTA) at a temperature in a range of from 300° C. to 1000° C. for a time period in a range of from 1 min to 10 hours in an ambient atmosphere of an inert gas, e.g., nitrogen (N₂), argon (Ar), or a mixture of nitrogen and argon (N₂/Ar).

In one or more embodiments, annealing the device 300 serves as a mechanism of metal-induced crystallization (MIC). Annealing the memory device 300 drives the metal, e.g., aluminum, from the capping layer 318 through the channel layer 316 to crystallize the polysilicon to form a single crystalline-like silicon layer. The amount of metal remaining at the single crystalline silicon is negligible, and the metal remains at the area far from memory cells. Thus, in one or more embodiments, the annealing of the device 300 results in the metal-induced crystallization of the channel layer 316, converting the channel layer 316 to a crystalline polysilicon layer 320 having a large grain size.

In one or more embodiments, during anneal of operation 112, the out-diffusion of aluminum (AI) from the capping layer 318 is prevented or minimized by the second aluminum oxide layer 318b. The amount of aluminum (Al) is controlled by how metal (aluminum) rich and how thick the first aluminum oxide layer 318a is. In one or more embodiments, the presence of the capping layer 318 advantageously increases the grain size of the channel layer 316 to form the crystalline polysilicon channel layer 320 during annealing.

Referring to FIG. 1 and FIGS. 3K and 3L, at operation 114, in one or more embodiments, the capping layer 318 is removed to expose the surface 321 of the crystalline polysilicon channel layer 320. In one or more embodiments, the capping layer 318 may be removed by any suitable means known to the skilled artisan. In one or more embodiments, the capping layer 318 is removed using hot phosphoric acid (H₃PO₄).

With reference to FIG. 1 and FIG M3, at operation 116, the memory hole 308 is filled with an oxide material 322. The oxide material 322 may comprise any suitable material. In one or more embodiments, the oxide material 322 comprises silicon oxide (SiOx).

Referring to FIG. 1 and FIG. 3N, at operation 118, a top portion of the oxide material 322 and the cell dielectric layer 314 are recessed or etched back to form a recess opening 323 in the memory hole 308. The recess opening 323 may have any suitable depth. In one or more embodiments, the recess opening has a depth in a range of from 100 nm to 300 nm.

FIG. 1 and FIG. 30 illustrate operation 120 of method 100 where a bit line pad 324 is formed on the top surface of the cell dielectric layers 314, the crystalline polysilicon layer 320, and on the oxide layer 322. The bit line pad 324 can be any suitable material known to the skilled artisan including, but not limited to, n-doped polysilicon. In one or more embodiments, when the bit line pad 324 is formed in the recess opening 323 a bit line or memory string is formed. While only a single bit line or memory string is shown in the illustrated embodiments, one of skill in the art recognizes that any number or plurality of bit lines or memory strings may be formed depending on how many memory holes were formed through the memory device.

Referring to FIG. 1 and FIG. 3P, at operation 122 of method 100, the memory stack 301 is slit patterned to form slit pattern openings 326 that extend from a top surface of the memory stack 301 to a top surface of the substrate 302.

With reference to FIG. 1 and FIG. 3Q, at operation 124, where the second layers 306, e.g., sacrificial layers are removed through the slit pattern opening 326 to form an opening 328. The second layers 306 can be removed by any suitable means known to the skilled artisan. In one or more embodiments, the second layers are removed by using one or more of selective etching, hot phosphoric acid, and the like.

Referring to FIG. 1 and FIGS. 3R and 3S, at operation 126, the word lines 330 are formed. In one or more embodiments, the word lines 330 include one or more of an oxide material, a nitride material, and a conductive metal. For example, in some embodiments, an aluminum oxide (Al) layer, a titanium nitride (TiN) layer, and tungsten (W) are deposited sequentially, and, as illustrated in FIG. 3S removed from the sidewall of the device 300 to form the word line 330.

With reference to FIG. 1 and FIG. 3T, at operation 128, in one or more embodiments, the slit pattern opening 326 is filled with an insulator material 332 to form a filled slit. The insulator material 332 may be any suitable material known to the skilled artisan. In one or more embodiments, the insulator material 332 is selected from one or more of silicon oxide, silicon nitride, and silicon oxynitride.

The method 100 illustrated in FIG. 1 may then proceed according to operation 130 with back end of the line processing to form a 3D NAND device, including formation of contacts and the like.

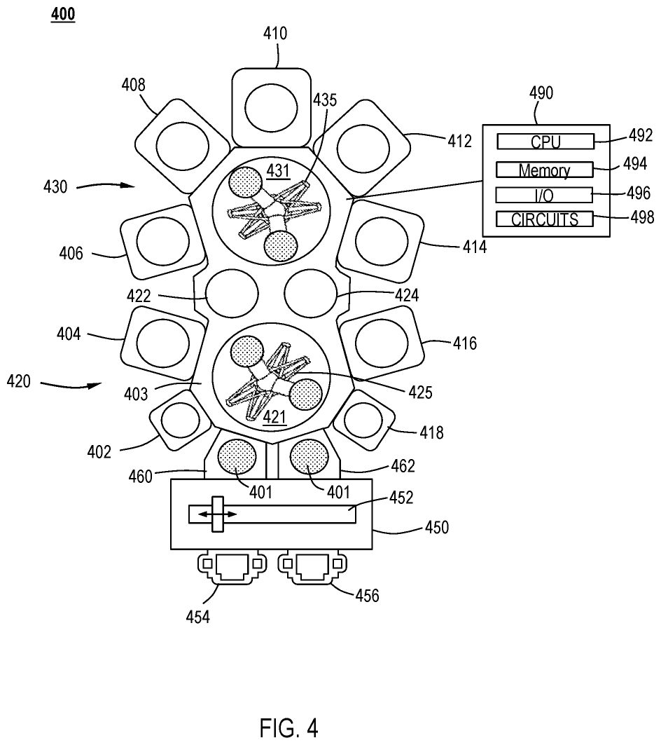

Additional embodiments of the disclosure are directed to processing tools 400 for the formation of the memory devices and methods described, as shown in FIG. 4.

The cluster tool 400 includes at least one central transfer station 421, 431 with a plurality of sides. A robot 425, 435 is positioned within the central transfer station 421, 431 and is configured to move a robot blade and a wafer to each of the plurality of sides.

The cluster tool 400 comprises a plurality of processing chambers 402, 404, 406, 408, 410, 412, 414, 416, and 418, also referred to as process stations, connected to the central transfer station. The various processing chambers provide separate processing regions isolated from adjacent process stations. The processing chamber can be any suitable chamber including, but not limited to, a preclean chamber, a buffer chamber, transfer space(s), a wafer orienter/degas chamber, a cryo cooling chamber, a deposition chamber, annealing chamber, etching chamber, or a word line deposition chamber. The particular arrangement of process chambers and components can be varied depending on the cluster tool and should not be taken as limiting the scope of the disclosure.

In some embodiments, the cluster tool 400 includes a metal-induced crystallization (MIC) annealing chamber.

In the embodiment shown in FIG. 4, a factory interface 450 is connected to a front of the cluster tool 400. The factory interface 450 includes a loading chamber 454 and an unloading chamber 456 on a front 451 of the factory interface 450. While the loading chamber 454 is shown on the left and the unloading chamber 456 is shown on the right, those skilled in the art will understand that this is merely representative of one possible configuration.

The size and shape of the loading chamber 454 and unloading chamber 456 can vary depending on, for example, the substrates being processed in the cluster tool 400. In the embodiment shown, the loading chamber 454 and unloading chamber 456 are sized to hold a wafer cassette with a plurality of wafers positioned within the cassette.

A robot 452 is within the factory interface 450 and can move between the loading chamber 454 and the unloading chamber 456. The robot 452 is capable of transferring a wafer from a cassette in the loading chamber 454 through the factory interface 450 to load lock chamber 460. The robot 452 is also capable of transferring a wafer from the load lock chamber 462 through the factory interface 950 to a cassette in the unloading chamber 456. As will be understood by those skilled in the art, the factory interface 450 can have more than one robot 452. For example, the factory interface 450 may have a first robot that transfers wafers between the loading chamber 454 and load lock chamber 460, and a second robot that transfers wafers between the load lock 462 and the unloading chamber 456.

The cluster tool 400 shown has a first section 420 and a second section 430. The first section 420 is connected to the factory interface 450 through load lock chambers 460, 462. The first section 420 includes a first transfer chamber 421 with at least one robot 425 positioned therein. The robot 425 is also referred to as a robotic wafer transport mechanism. The first transfer chamber 421 is centrally located with respect to the load lock chambers 460, 462, process chambers 402, 404, 416, 418, and buffer chambers 422, 424. The robot 425 of some embodiments is a multi-arm robot capable of independently moving more than one wafer at a time. In some embodiments, the first transfer chamber 421 comprises more than one robotic wafer transfer mechanism. The robot 425 in first transfer chamber 421 is configured to move wafers between the chambers around the first transfer chamber 421. Individual wafers are carried upon a wafer transport blade that is located at a distal end of the first robotic mechanism.

After processing a wafer in the first section 420, the wafer can be passed to the second section 430 through a pass-through chamber. For example, chambers 422, 424 can be uni-directional or bi-directional pass-through chambers. The pass-through chambers 422, 424 can be used, for example, to cryo cool the wafer before processing in the second section 430 or allow wafer cooling or post-processing before moving back to the first section 420.

A system controller 490 is in communication with the first robot 425, second robot 935, first plurality of processing chambers 402, 404, 416, 418 and second plurality of processing chambers 406, 408, 410, 412, 414. The system controller 490 can be any suitable component that can control the processing chambers and robots. For example, the system controller 490 can be a computer including a central processing unit, memory, suitable circuits, and storage.

Processes may generally be stored in the memory of the system controller 490 as a software routine that, when executed by the processor, causes the process chamber to perform processes of the present disclosure. The software routine may also be stored and/or executed by a second processor (not shown) that is remotely located from the hardware being controlled by the processor. Some or all of the methods of the present disclosure may also be performed in hardware. As such, the process may be implemented in software and executed using a computer system, in hardware as, e.g., an application specific integrated circuit or other type of hardware implementation, or as a combination of software and hardware. The software routine, when executed by the processor, transforms the general-purpose computer into a specific purpose computer (controller) that controls the chamber operation such that the processes are performed.

The use of the terms “a” and “an” and “the” and similar referents in the context of describing the materials and methods discussed herein (especially in the context of the following claims) are to be construed to cover both the singular and the plural, unless otherwise indicated herein or clearly contradicted by context. Recitation of ranges of values herein are merely intended to serve as a shorthand method of referring individually to each separate value falling within the range, unless otherwise indicated herein, and each separate value is incorporated into the specification as if it were individually recited herein. All methods described herein can be performed in any suitable order unless otherwise indicated herein or otherwise clearly contradicted by context. The use of any and all examples, or exemplary language (e.g., “such as”) provided herein, is intended merely to better illuminate the materials and methods and does not pose a limitation on the scope unless otherwise claimed. No language in the specification should be construed as indicating any non-claimed element as essential to the practice of the disclosed materials and methods.

Reference throughout this specification to “one embodiment,” “certain embodiments,” “one or more embodiments” or “an embodiment” means that a particular feature, structure, material, or characteristic described in connection with the embodiment is included in at least one embodiment of the disclosure. Thus, the appearances of the phrases such as “in one or more embodiments,” “in certain embodiments,” “in one embodiment” or “in an embodiment” in various places throughout this specification are not necessarily referring to the same embodiment of the disclosure. Furthermore, the particular features, structures, materials, or characteristics may be combined in any suitable manner in one or more embodiments.

Although the disclosure herein has been described with reference to particular embodiments, it is to be understood that these embodiments are merely illustrative of the principles and applications of the present disclosure. It will be apparent to those skilled in the art that various modifications and variations can be made to the method and apparatus of the present disclosure without departing from the spirit and scope of the disclosure. Thus, it is intended that the present disclosure include modifications and variations that are within the scope of the appended claims and their equivalents.

What is claimed is:

1. A method of forming a semiconductor device, the method comprising:
depositing a silicon layer on a substrate, the silicon layer having a grain size less than 0.1 μm;
depositing a capping layer on the silicon layer, the capping layer comprising a metal oxide; and
annealing the substrate at a temperature in a range of from 300° C. to 1100° C. to increase the grain size of the silicon layer.

2. The method of claim 1, wherein the silicon layer has a thickness in a range of from 5 nm to 100 nm, and wherein the capping layer has a thickness in a range of from 1 nm to 50 nm.

3. The method of claim 1, wherein the metal oxide comprises a metal selected from one or more of aluminum (Al), nickel (Ni), cobalt (Co), zirconium (Zr), and palladium (Pd).

4. The method of claim 1, wherein the capping layer is a bilayer comprising a first metal oxide layer having a thickness in a range of from 0.5 nm to 5 nm and a second metal oxide layer having a thickness in a range of from 1 nm to 50 nm.

5. The method of claim 4, wherein the first metal oxide layer has a composition of MOₓ, wherein 0≤x≤1.

6. The method of claim 5, wherein the metal of the first metal oxide layer comprises aluminum, and the first metal oxide layer has a composition of Al₂O_{(3+δ)}, wherein 0<δ≤3.

7. The method of claim 4, wherein the second metal oxide layer has a composition of MO_{y}, wherein y≥1.

8. The method of claim 7, wherein the metal of the second metal oxide layer comprises aluminum, and the second metal oxide layer has a composition of Al₂O_{(3+δ)}, wherein δ≥0.

9. The method of claim 1, further comprising removing the capping layer to expose the silicon layer.

10. A method of forming a semiconductor memory device, the method comprising:
depositing cell dielectric layers in a plurality of memory holes extending through a memory stack, the memory stack comprising a plurality of alternating layers of a first layer and a second layer on a substrate;
depositing a silicon layer on the cell dielectric layer, the silicon layer having a grain size less than 0.1 μm;
depositing a capping layer on the silicon layer, the capping layer comprising a first aluminum oxide layer having a composition of Al₂O_{(3+δ)}, wherein 0<δ≤3, and a second aluminum oxide layer having a composition of Al₂O_{(3+δ)}, wherein δ≥0; and
annealing the substrate at a temperature in a range of from 300° C. to 1100° C. to increase the grain size of the silicon layer.

11. The method of claim 10, wherein the silicon layer has a thickness in a range of from 5 nm to 100 nm, wherein the first aluminum oxide layer has a thickness in a range of from 0.5 nm to 5 nm, and wherein the second aluminum oxide layer has a thickness in a range of from 1 nm to 50 nm.

12. The method of claim 10, further comprising removing the capping layer to expose the silicon layer.

13. The method of claim 12, further comprising
depositing an oxide layer in the plurality of memory holes on the silicon layer; and
recessing the oxide layer, the cell dielectric layers, and the silicon layer to form a recess opening.

14. The method of claim 13, further comprising forming a bit line pad in the recess opening to form a plurality of memory strings.

15. The method of claim 14, further comprising forming a slit extending through the memory stack to the substrate adjacent to the plurality of memory strings.

16. The method of claim 15, further comprising
removing each second layer to form an opening in the memory stack; and
depositing one or more of an oxide material, a nitride material, and a conductive material into the opening to form a plurality of word lines.

17. The method of claim 16, further comprising filling the slit to form a filled slit.

18. The method of claim 10, wherein the cell dielectric layers comprise one or more of a blocking oxide layer, a trap layer, and a tunnel oxide layer.

19. The method of claim 11, wherein the first layer comprises an oxide layer and the second layer comprises a nitride layer.

20. The method of claim 9, wherein the semiconductor memory device is a 3D NAND device.
